(19) United States
(12) Patent Application Publication
(10) Pub. No.: US 2026/0302742 A1
(43) Pub. Date: Oct. 1, 2026

(54) QUANTUM COMPUTER CABLE ASSEMBLY AND QUANTUM COMPUTER CABLE HOLDER

(71) Applicant: Rohde & Schwarz GmbH & Co. KG, Muenchen (DE)

(72) Inventors: Fabian SCHENKEL, Zurich (CH); David MUELLER, Zurich (CH); Benjamin SCHMID, Zurich (CH)

(21) Appl. No.: 19/544,014

(22) Filed: Feb. 19, 2026

(30) Foreign Application Priority Data
Mar. 31, 2025 (DE) 10 2025 112 433.7

(51) Int. Cl. H02G 3/04; G06F 1/18

(52) U.S. Cl. CPC H02G 3/0456; G06F 1/181

(57) ABSTRACT

A quantum computer cable assembly for a quantum computer and a quantum computer cable holder are provided. The quantum computer cable assembly includes at least two quantum computer control cables for the quantum computer that are configured to transmit radio frequency signals. The quantum computer cable assembly also includes a cable receptacle for the quantum computer control cables. The cable receptacle includes at least two cable guides which are separate from each other and which are each configured to fix at least one of the at least two quantum computer control cables for the quantum computer in place with a form fit such that the quantum computer control cables are received in the respective cable guide so as to preserve their positions.

### CROSS-REFERENCE(S) TO RELATED APPLICATION(S)

This application claims priority to German Application No. 10 2025 112 433.7, filed Mar. 31, 2025, the entire disclosure of which is enclosed herein in its entirety.

### FIELD OF THE DISCLOSURE

The present disclosure relates to a quantum computer cable assembly for a quantum computer and a quantum computer cable holder.

### BACKGROUND

The size of quantum computer processors (QPUs) increases exponentially, and so does the number of control lines required between a QPU and a room temperature electronics module (RTE). Each qubit on the QPU requires multiple RF control lines (RF: radio frequency) and/or RF readout lines for coupling to the RTE.

To date, QPUs with up to several dozen qubits have been built. In this context, the RTE and the QPU have so far been individually and manually prepared and wired in laboratories with regard to the respective RF lines. This involves high manufacturing cost and effort. In addition, this contributes to an increased error rate, since automated wiring techniques cannot be used so far. For example, the RF lines cannot be addressed individually, so that a manual cabling error between mutually assigned connections of the RTE and the QPU cannot be compensated for in the control in terms of software. Such a cabling error cannot be easily identified using diagnostic programs. Rather, a manual examination is required, which in turn increases the manufacturing costs.

Furthermore, a very rigid cable trajectory is necessary with regard to the RF lines in order to achieve the required high phase stability of the RF signals sent to the QPU. Otherwise, the RF signals would be subject to phase drift if the cable is subjected to deformation, which would affect the operation of the QPU. In other words, phase stability would no longer be ensured.

Many laboratories therefore use semi-rigid cables to minimize deformation of the cables and thereby increase the phase stability of the RF signals. However, this involves additional installation effort and greatly reduced flexibility during cabling and during operation, for example when maintaining or expanding existing systems. Therefore, the scalability of existing systems is limited, which, however, is necessary to increase the performance of QPUs.

Therefore, a need exists to make the cable feed line for a quantum computer less complex and more robust, while at the same time allowing a reduced error rate in the cabling of the quantum computer.

### SUMMARY

This need or others is satisfied according to aspects of the present disclosure, for example, by a quantum computer cable assembly for a quantum computer. In an embodiment, the quantum computer cable assembly includes at least two quantum computer control cables for the quantum computer. The quantum computer control cables are configured to transmit radio frequency signals (RF signals). The quantum computer cable assembly includes a cable receptacle for the quantum computer control cables. The cable receptacle includes at least two cable guides that are separate from each other. The cable guides are each configured to fix at least one of the at least two quantum computer control cables for the quantum computer in place with a form fit such that the quantum computer control cables are received in the respective cable guide so as to preserve their positions.

The present disclosure is based on the finding that a plurality of quantum computer control cables (hereinafter “QC” for quantum computer) can be fixed in place in a single cable receptacle. This not only fixes each QC control cable individually, i.e., it is received so as to retain its position, but also fixes the at least two QC control cables in place relative to each other. This provides a robust routing of the QC control cables with an increased packing density. Furthermore, this allows a desired trajectory of the QC control cables, thereby achieving increased phase stability of the RF signals. This makes the operation of the QC more stable, which increases its performance. In addition, the QC cable assembly also allows the error rate in the course of the cabling process to be reduced, since the cable receptacle reduces the probability of incorrect coupling of connections assigned to each other, for example. Moreover, the defined cable routing of the QC control cables also results in improved scalability and identifiability of individual QC control cables, so that the effort required for maintenance and modification of the QC is reduced. Furthermore, the QC cable assembly allows automated cabling techniques to be employed, so that cabling no longer needs to be done individually and manually in the laboratory. For example, the QC cable assembly can be prefabricated at a production facility. Transporting QC cable assemblies instead of individual QC control cables to the QC production site, such as, e.g., a laboratory, significantly reduces the amount of work and time required for cabling.

In an embodiment, the QC control cables are configured to transmit RF signals. RF signals are considered to be signals having a frequency of 1 MHz or greater, for example 1 GHz or greater, preferably 10 GHz or more, more preferably 100 GHz or more, and up to 500 GHz. This allows the qubits of the QC to be operated at high clock frequencies.

According to one aspect, the QC control cables, for example, may be coaxial cables. This allows high signal quality and phase stability to be ensured, since a circumferential shielding of the inner conductor is made possible.

In an embodiment, the QC cable assembly includes a single cable receptacle. This makes the QC cable assembly compact and allows it to be manufactured using fewer individual components.

Optionally, the cable guides of a cable receptacle are arranged adjacent to each other (linearly) corresponding to a straight axis. This also allows a defined routing of the QC control cables.

In an embodiment, the QC cable assembly is formed such that the cable receptacle includes cable guides for at least five, preferably seven, QC control cables. This allows a defined group of QC control cables to be fixed in an accurate position in a single cable receptacle, which simplifies the cabling of the QC.

Optionally, the QC cable assembly is configured such that the QC control cables fixed in place in the cable receptacle can be coupled, on the one hand, to an RTE and, on the other hand, to a control card or a control connection of the QC. In this way, a direct coupling between the RTE and the QC is possible.

In an embodiment, each of the cable guides is configured to fix one respective individual QC control cable in place. This allows each cable guide to be adjusted to a specific QC control cable, thereby increasing the accuracy of fit.

In some embodiments, the cable guides may each have a cross-sectional contour that corresponds to a cross-sectional contour of the QC control cable received in the respective cable guide. In this way, each cable guide is individually adapted to the corresponding QC control cable. For example, this also allows QC control cables having different cross-sectional contours to be fixed so as to retain their position in the respective cable guide, for example, if QC control cables with single shielding are used, on the one hand, and QC control cables with multiple shielding are used, on the other hand.

According to one aspect, at least one cable guide, for example, has a length along which the respective QC control cable is fixed in place therein. Along this length, the cable guide has a curved trajectory, that is, a curved contact surface. A corresponding radius of curvature matches a specified minimum radius of curvature or a (specified) radius of curvature of the QC control cable received in the cable guide. The curvature of the QC control cable may have an influence on the phase of the signal transmitted by the QC control cable. For QC control cables, a desired radius of curvature and/or a minimum radius of curvature may therefore be specified for a trajectory of the QC control cable. The respective cable guide may be designed in accordance with one of these specifications. This increases the phase stability of the RF signals transmitted by the QC control cable.

Optionally, the cable guides are formed side by side and partially merge into one another. This allows a defined but compact arrangement of the QC control cables to be realized. The cable guides that merge into one another reduce the installation space required for the QC cable assembly. In addition, the individual QC control cables can be introduced into the cable guides provided, for example, one after the other from a front side of the cable receptacle.

In an embodiment, the cable receptacle has an insertion contour for the QC control cables, for example on the front side of the cable receptacle. The front side may be accessible to an operator. This allows the QC control cables to be conveniently introduced into the cable guides and placed therein. For example, this avoids the need for the QC control cables to be threaded into the cable guides lengthwise, which would increase the effort involved.

In other words, the insertion contour is provided on the side of the cable receptacle that extends parallel to the axes of the cable guides. This means that the individual QC control cables need not be threaded in by their ends, but rather are inserted into the cable receptacle via the insertion contour.

Since the cable guides partially merge into one another, the QC control cable inserted into the insertion contour can then be pushed into the intended cable guide by pushing it from the cable guide directly adjacent to the insertion contour up to the desired cable guide.

In an embodiment, the individual cable guides each have a cross-sectional contour that results in narrow points between neighboring cable guides, whereby positioning aids are obtained. However, it is possible to push the QC control cables over the narrow points to move from one cable guide to the neighboring cable guide.

In one aspect, the cable receptacle, for example, may be formed in multiple parts. In that case, the cable receptacle may include at least a first cable receptacle part and a second cable receptacle part. In this case, the cable receptacle may include at least one snap-in connection that is adapted to be released non-destructively so that the QC control cables can be placed in or removed from the cable guides. In an embodiment, in this way, all QC control cables can be inserted simultaneously in a simple manner. This allows an even more convenient placement of the QC control cables, since the opening angle for inserting the QC control cables is made larger. Manufacturing the QC cable assembly then requires little effort. In addition, the snap-in connection allows a secure and robust positioning of the individual cable receptacle parts in relation to each other, which, however, can be conveniently released. In this way, the effort required for maintenance work is also reduced, for example, if a QC control cable needs to be replaced.

In some embodiments, the first cable receptacle part may include at least one projection and the second cable receptacle part may include at least one depression. The depression is formed to correspond to the projection. In an embodiment, the projection and the depression are formed to correspond to each other in terms of shape, so that the projection can be inserted into the depression to be fixed in place therein with a form fit, a friction fit, and/or a force fit. This allows a robust but releasable coupling of the cable receptacle parts with each other to be realized in an efficient manner in order to form the snap-in connection.

In an embodiment, the snap-in connection may comprise two projections and two depressions, which are each formed to correspond to each other in pairs. In this way, the coupling strength between the cable receptacle parts can be increased with regard to the snap-in connection. In the event of an incorrect connection of a first projection-depression connection, the snap-in connection can still be held securely by the further projection-depression connection. The individual projection-depression connections can therefore be redundant in relation to each other.

A single cable receptacle part may include either two projections or two depressions, or one projection and one depression each, or, of course, three or more selected from projections and depressions. In the event that each cable receptacle part includes both at least one projection and one depression, the cable receptacle parts may overall be identical in construction, i.e., have an identical shape, whereby the effort required to manufacture the cable receptacle parts can be reduced.

In an embodiment, the plurality of projections or depressions, or the single projection and the single depression of a single cable receptacle part, may be arranged at spaced-apart positions on the cable receptacle part, provided that the snap-in connection is closed. This allows the cable receptacle parts to be completely detached from each other when the snap-in connection has been released. Furthermore, the spaced positioning results in reduced play in the snap-in connection, so that the preservation of position of the cable receptacle parts relative to each other is increased.

Optionally, the snap-in connection is adapted to be released non-destructively such that all of the QC control cables that can be fixed in place in the cable guides can be placed therein or removed therefrom simultaneously. This allows the QC control cables to be fixed and/or released jointly, reducing the amount of cabling required.

In an embodiment, the cable receptacle parts each have part-circle-shaped recesses. The part-circle-shaped recesses of the first cable receptacle part and of the second cable receptacle part face each other and together form the cable guides when the cable receptacle parts are coupled to each other. In this way, each cable receptacle part contributes to guiding the cables in equal measure, thereby avoiding one-sided stress on the cable receptacle parts and/or the QC signal cables. In addition, the cable receptacle parts can then be identical in construction.

In some embodiments, the QC cable assembly may also include a plurality of cable receptacles that are identical in construction and arranged to be spaced apart from each other along the length of the QC control cables. For example, one cable receptacle may be assigned to the coupling point between the QC cable assembly and the QC, and another cable receptacle may be assigned to the coupling point between the QC cable assembly and the RTE. Here, the QC control cables may be arranged in the various cable receptacles according to a uniform order. This reduces the effort involved in installation and maintenance, since the QC control cables then do not need to be traced along their length or need to have other identification features (markings) for identification purposes. For example, to identify a specific QC control cable, it is simply only necessary to identify the first QC control cable in the cable receptacles corresponding to each other. The further QC control cables can then be identified by the position within the group of QC control cables that are jointly accommodated in the respective cable receptacles.

According to a different aspect, the need or others is also satisfied according to the present disclosure by a QC cable holder for a QC. In an embodiment, the QC cable holder comprises a QC cable assembly as described above. The QC cable holder includes a carrier receptacle in which at least the cable receptacle of the QC cable assembly can be received, for example received so as to be non-destructively releasable. The position of the cable receptacle in relation to the QC can thus be reversibly determined. This results in the QC control cables fixed in place in the cable receptacle being aligned in a defined manner with respect to the QC. This alignment allows a higher phase stability of the RF signals transmitted in the QC control cables to be obtained.

According to some embodiments, the cable holder includes a QC connection interface by which the cable holder can be fitted to the QC. This allows a mechanical coupling of the QC control cables to the QC, so that the transmission of the signals is optimized. For example, the cable holder may be adapted to be fitted to a housing of the QC.

In an embodiment, the coupling between the QC cable assembly and the QC by the connection interface may provide for a specific order of the QC control cables in order to couple them to corresponding inputs of the QC or a control card thereof. The QC cable holder may then be designed such that the cable guides of the cable receptacle have an order such that the QC control cables received in the cable guides are designed in accordance with the order according to which the QC control cables are to be coupled to the inputs of the QC. This is advantageous, for example, if the QC control cables have different cross-sectional contours. In this case, individual QC control cables do not need to be crossed with each other to couple them to the inputs of the QC.

In an embodiment, the connection interface may be part of a control card or part of a bay or of the QC (corresponding to the bays of a rack).

Optionally, the carrier receptacle may be designed such that at least two cable receptacles can be received therein. Since the QC has to be coupled to the RTE using a multitude of QC control cables, this allows the scalability to be increased so that QC control cables can be installed or detached in groups, for example also for maintenance work.

In an embodiment, the carrier receptacle has a slot into which or through which the QC control cables can be led, for example in order to accommodate the cable receptacle in the carrier receptacle. This allows simple assembly using coupling.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 to FIG. 5 show various schematic illustrations of a quantum computer cable assembly according to one or more embodiments of the present disclosure;

FIG. 6 and FIG. 7 show various schematic illustrations of a quantum computer cable holder according to one or more embodiments of the present disclosure; and

FIG. 8 shows a schematic illustration of an assembly with part of a quantum computer and a quantum computer cable holder.

All features mentioned below in relation to the example embodiments and/or the accompanying figures can be combined alone or in any sub combination with features of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

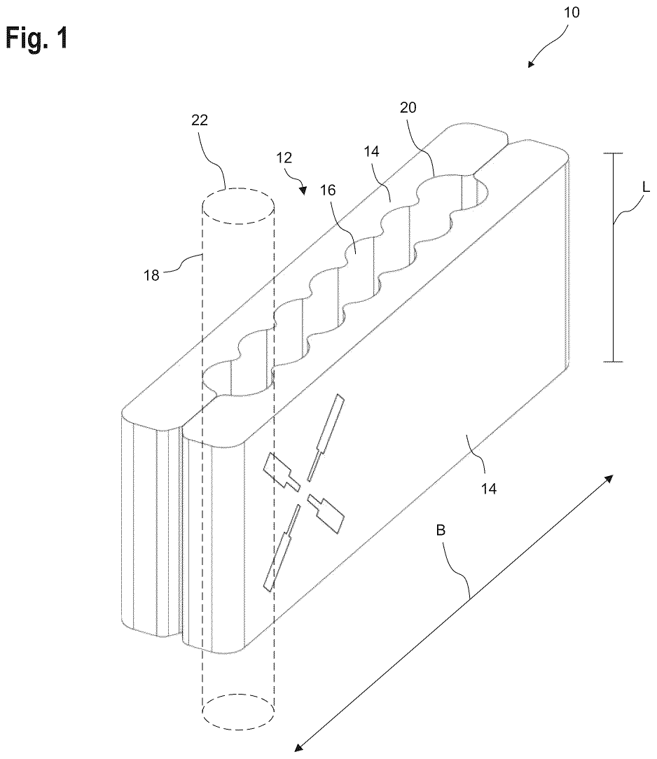

FIGS. 1 to 5 show various schematic illustrations of a quantum computer cable assembly 10 according to one or more embodiment of the present disclosure. According to this embodiment, the QC cable assembly 10 comprises a cable receptacle 12 that includes two cable receptacle parts 14. The two cable receptacle parts 14 cooperate to form the cable receptacle 12. The cable receptacle parts 14 here form a plurality of cable guides 16 formed next to each other along the width B of the cable receptacle 12.

Each cable guide 16 is configured to fix therein an individual QC control cable 18 for a QC with a form fit, so that the QC control cables 18 are received in the respective cable guides 16 so as to preserve their positions. The QC control cables 18 are received in the respective cable guides 16 for example with a form fit and/or a friction fit and/or a force fit. The cable guides 16 each have a cross-sectional contour 20 that matches the cross-sectional contour 22 of the QC control cable 18 to be received therein.

The cable receptacle parts 14 each have part-circle-shaped recesses 23 that face each other in pairs and together form the cross-sectional contour 20 of the cable guides 16 if the cable receptacle parts 14 are coupled to each other. The cable receptacle parts 14 of the cable receptacle 12 have a length L along which the respective QC control cables 18 extend in the cable guides 16. The QC control cables 18 are therefore fixed in place in the cable receptacle 12 over the length L, rather than only at certain points. This reduces play.

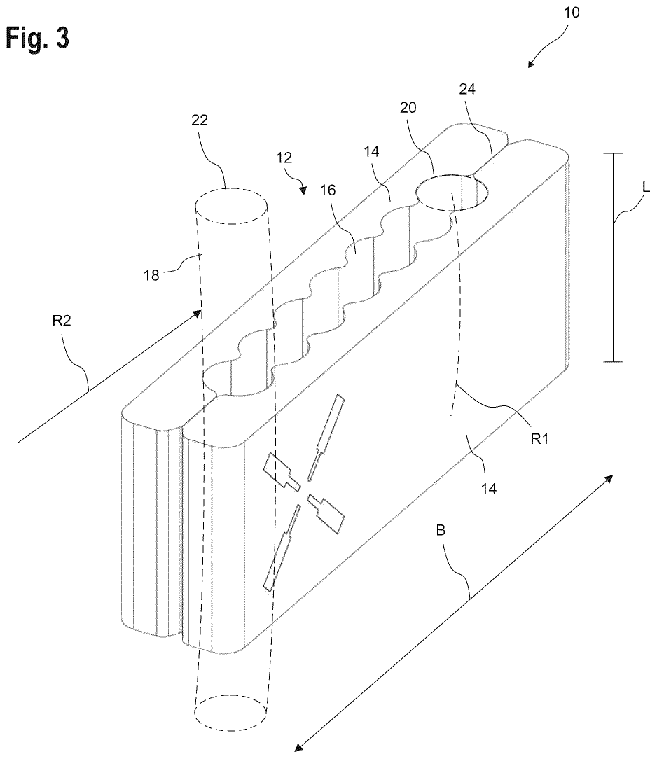

FIG. 3 clearly shows that the cable guides 16 of the cable receptacle 12 formed by the cable receptacle parts 14 may have a curved trajectory along the length L. In this case, the cable guides 16 are not linear. Nonetheless, the cross-sectional contour 20 can be ensured in each section along the length L. The curved trajectory of the cable guides 16 here has a radius of curvature R1 that is identical to a desired radius of curvature R2 or a minimum radius of curvature of the QC control cables 18. In this way, it can be ensured that the target trajectory for guiding the QC control cables 18 is not prevented due to the fixing in place in the cable receptacle 12.

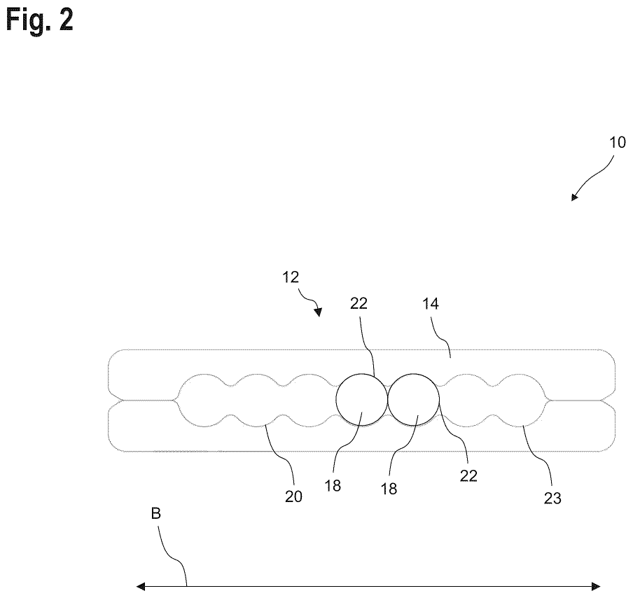

Even though the cable guides 16 merge into one another in accordance with this embodiment, they may in principle also be designed to be completely separate from one another. This means that, in accordance with this embodiment, the cross-sectional contours 20 of the individual cable guides 16 are formed only in sections rather than completely. This is also apparent, for example, from the top view in FIG. 2.

In one alternative embodiment, while the cross-sectional contours 20 may be formed by recesses 23 of the respective cable receptacle parts 14, they may each be formed separately from one another and completely. The cable guides 16 then do not merge into one another.

Basically, the QC control cables 18 may be designed and configured as coaxial cables to conduct RF signals, for example between an RTE and the QC.

The two cable receptacle parts 14 are attached to each other so as to be non-destructively reversibly releasable. They can be released from each other to expose an insertion contour 24 that can be utilized to place the QC control cables 18 into the respective cable guides 16.

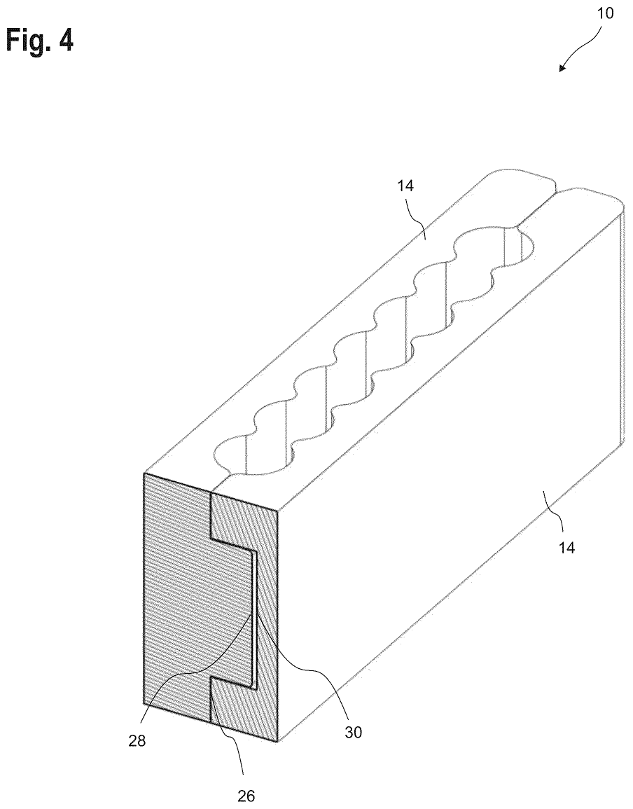

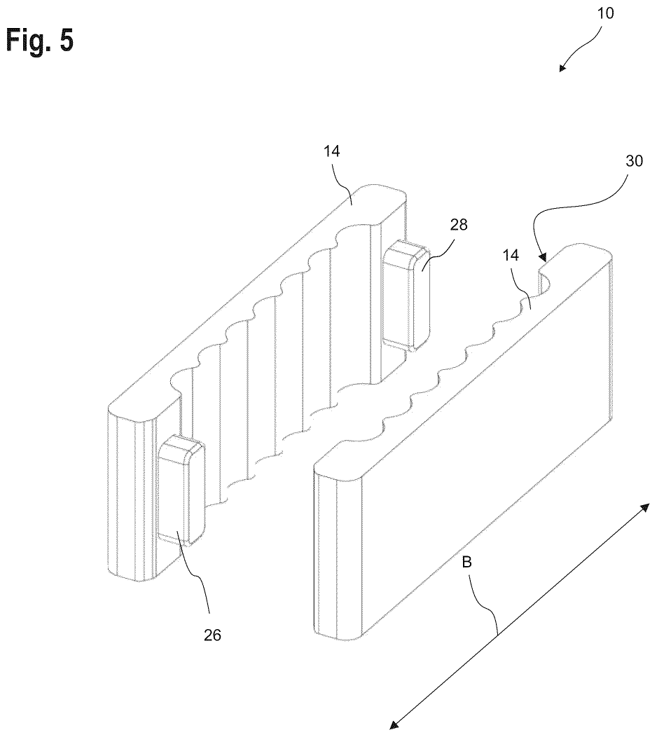

FIG. 4 and FIG. 5 show that the cable receptacle 12 may have a snap-in connection 26, by which the cable receptacle parts 14 can be coupled to each other so as to be non-destructively releasable. This allows the position preservation of the cable receptacle parts 14 in relation to each other to be ensured. At the same time, the cable receptacle parts 14 can be released from each other, making it easier to insert the QC control cables 18.

The snap-in connection 26 comprises at least one projection 28 and one depression 30. The projection 28 and the depression 30 comprise mutually corresponding shapes so that the projection 28 can be introduced into the depression 30. The projection 28 and the depression 30 are then coupled to each other by a form fit and/or a friction fit and/or a force fit, so that the QC control cables 18 are fixed in place in the cable guides 16.

Each cable receptacle part 14 may also include a plurality of projections 28 or a plurality of depressions 30, or at least one projection 28 and one depression 30 each. The plurality of components of a cable receptacle part 14 involved in the snap-in connection 26 may be formed to be spaced apart from each other along the width B of the cable receptacle part 14. This reduces the play of the snap-in connection 26.

If the cable receptacle 12 includes an insertion contour 24 via which the QC control cables 18 are to be inserted in the closed state of the cable receptacle 12, a snap-in connection 26 should not be provided at the side of the insertion contour 24 in order to allow insertion via the insertion contour 24.

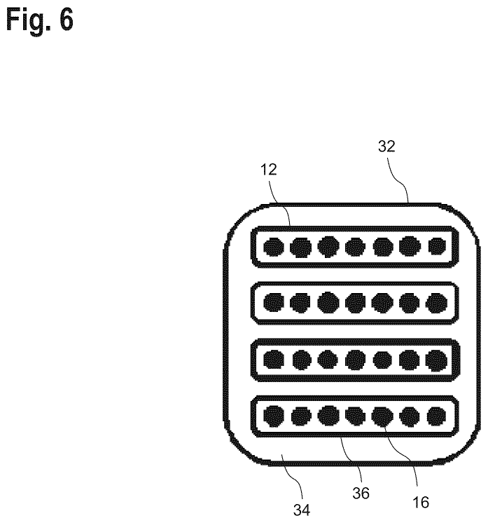

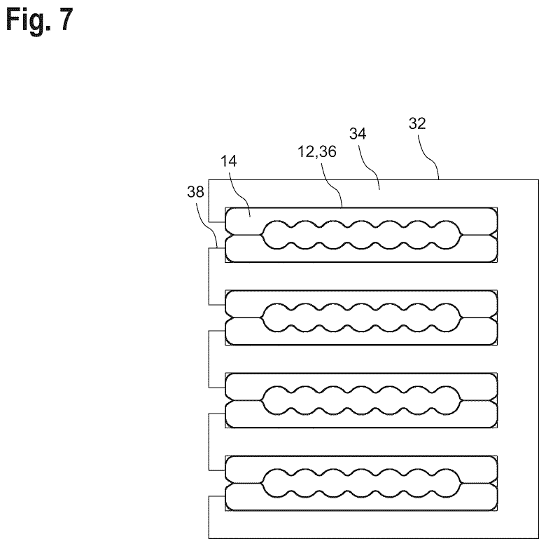

FIG. 6 and FIG. 7 show various schematic illustrations of one or more embodiments of a quantum computer cable holder 32 according to the present disclosure. The QC cable holder 32 includes a carrier receptacle 34 in which a plurality of cable receptacles 12 from different QC cable assemblies 10 are accommodated. To this end, the carrier receptacle 34 has receiving contours 36 that have a shape that is formed to correspond to the outer shape of the cable receptacles 12. Here, four separate cable receptacles 12 are received in the carrier receptacle 34 at a distance from one another along a specific direction.

FIG. 7 illustrates that the carrier receptacle 34 has slots 38 through which the cable receptacles 12 and/or QC control cables 18 can be inserted into the receiving contours 36 of the carrier receptacle 34.

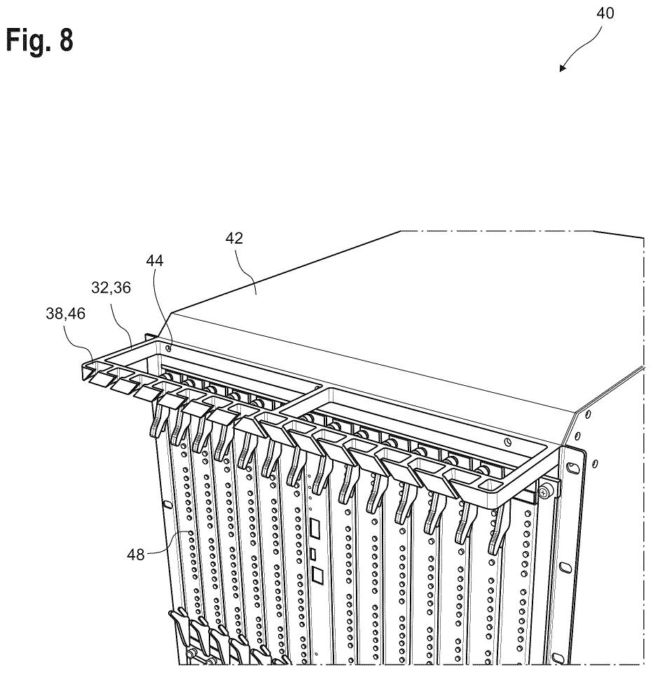

FIG. 8 shows a schematic illustration of an assembly 40 with part of a QC 42, in this case a rack, and a QC cable holder 32. The QC cable holder 32 comprises a connection interface 44 by means of which the QC cable holder 32 can be mounted to the QC 42, for example to a housing thereof. According to this configuration of the QC cable holder 32, the slots 38 are separate from the receiving contours 36. That is, while a plurality of cable receptacles 12 can be arranged in separate receiving contours 36, the QC control cables 18 may additionally be arranged in guides 46 into which the QC control cables 18 can be inserted using the slots 38. This allows the QC cable assemblies 10 with the QC control cables 18 to be aligned in a defined and orderly manner, which allows for clear cable routing and increased packing density.

Proceeding from the cable receptacles 12 or the guides 46, the QC control cables 18 can then be coupled to appropriate inputs 48 of the QC.

Generally, the signals transmitted by QC control cables 18 are influenced by movements of the QC control cables 18. For example, movement may result in a phase change in the RF signal transmitted. These problems do not exist for conventional data communication cables, such as network cables.

The cable receptacles 12 and/or the carrier receptacles 34 increase the positional fidelity of the QC control cables 18. This results in less movement due to external influences and thus higher phase stability of the signals transmitted by the QC control cables 18.

The defined fixing of the QC control cables 18 in place in the cable receptacles 12 also results in the QC control cables 18 being protected against external influences. In addition, clarity is increased, so that the risk of cabling errors is reduced. Furthermore, the QC cable assemblies 10 can be prefabricated at a manufacturer's premises and then coupled to the QC 42 as a whole. The cable guides 16 allow a clearer arrangement of the QC control cables 18 in accordance with a specific order, so that individual QC control cables 18 can be identified more efficiently, which, for example, reduces maintenance effort.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A quantum computer cable assembly for a quantum computer, comprising at least two quantum computer control cables for the quantum computer that are configured to transmit radio frequency signals, and a cable receptacle for the quantum computer control cables, wherein the cable receptacle includes at least two cable guides which are separate from each other and which are each configured to fix at least one of the at least two quantum computer control cables for the quantum computer in place with a form fit such that the quantum computer control cables are received in the respective cable guide so as to preserve their positions.

2. The quantum computer cable assembly according to claim 1, wherein each of the cable guides is configured to fix one respective individual quantum computer control cable in place.

3. The quantum computer cable assembly according to claim 1, wherein the cable guides each have a cross-sectional contour that corresponds to a cross-sectional contour of the quantum computer control cable received in the respective cable guide.

4. The quantum computer cable assembly according to claim 1, wherein the cable guides are formed side by side and partially merge into one another.

5. The quantum computer cable assembly according to claim 1, wherein the cable receptacle has an insertion contour for the quantum computer control cables.

6. The quantum computer cable assembly according to claim 1, wherein the cable receptacle is formed in multiple parts and includes a first cable receptacle part and a second cable receptacle part, and wherein the cable receptacle has at least one snap-in connection that is adapted to be released non-destructively so that the quantum computer control cables can be placed in or removed from the cable guides.

7. The quantum computer cable assembly according to claim 6, wherein the first cable receptacle part includes at least one projection and the second cable receptacle part includes at least one depression that is formed to correspond to the projection, wherein the snap-in connection comprises two projections and two depressions.

8. The quantum computer cable assembly according to claim 6, wherein the snap-in connection is adapted to be released non-destructively such that all of the quantum computer control cables that can be fixed in place in the cable guides can be placed therein or removed therefrom simultaneously.

9. The quantum computer cable assembly according to claim 6, wherein the cable receptacle parts each have part-circle-shaped recesses, wherein the part-circle-shaped recesses of the first cable receptacle part and of the second cable receptacle part face each other and together form the cable guides.

10. A quantum computer cable holder for a quantum computer, comprising a quantum computer cable assembly according to claim 1, wherein the quantum computer cable holder includes a carrier receptacle in which at least the cable receptacle of the quantum computer cable assembly can be received.

11. The quantum computer cable holder according to claim 10, wherein the quantum computer cable holder includes a quantum computer connection interface by means of which the quantum computer cable holder can be fitted to the quantum computer.

12. The quantum computer cable holder according to claim 10, wherein the carrier receptacle is designed such that at least two cable receptacles can be received therein.
